(19) United States
(12) Patent Application Publication
(10) Pub. No.: US 2013/0335103 A1
(43) Pub. Date: Dec. 19, 2013

(54) LINE IMPEDANCE STABILIZATION NETWORK

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventor: YONG-SHENG YANG, Shenzhen (CN)

(21) Appl. No.: 13/921,214

(22) Filed: Jun. 19, 2013

(30) Foreign Application Priority Data
Jun. 19, 2012 (CN) 2012102027334

(51) Int. Cl. G01R 31/00

(52) U.S. Cl. CPC G01R 31/001
USPC 324/613

(57) ABSTRACT

A line impedance stabilization network (LISN) includes a power port for connecting to a power supply, an equipment under test (EUT) connection port for connecting to an EUT, and a first inductor connected between the power port and the EUT connection port. The coil includes a first end, an opposite second end, a wire connected between the first end and the second end, and a first resistor. The wire includes a plurality of coils, and the first resistor is connected between two different coils of the wire.

### BACKGROUND

1. Technical Field

The present disclosure relates to electromagnetic interference (EMI) test technology, and more particularly to a line impedance stabilization network (LISN).

2. Description of Related Art

A line impedance stabilization network (LISN) is peripheral equipment which is used in an EMI test process. Generally, the LISN is connected between an electric supply and equipment under test (EUT) and EMI test equipment. The EMI test equipment can obtain accurate EMI data of the EUT via the LISN. The LISN usually includes inductors, and coils of the inductor are usually made from copper wire and a plastic cover covering the copper wire. However, because the inductors cannot conduct a large current, reliability of the LISN may be reduced.

What is needed is to provide a means that can overcome the above-described limitations.

### BRIEF DESCRIPTION OF THE DRAWINGS

The components in the drawings are not necessarily drawn to scale, the emphasis instead placed upon clearly illustrating the principles of at least one embodiment. In the drawings, like reference numerals designate corresponding parts throughout the various views, and all the views are schematic.

FIG. 1 is a circuit diagram of an LISN according to an embodiment of the present disclosure.

FIG. 2 is an isometric view of a first inductor of the LISN of FIG. 1.

FIG. 3 is a cross-sectional view of a wire of the first inductor of FIG. 2.

### DETAILED DESCRIPTION

Reference will now be made to the drawings to describe certain exemplary embodiments of the present disclosure in detail.

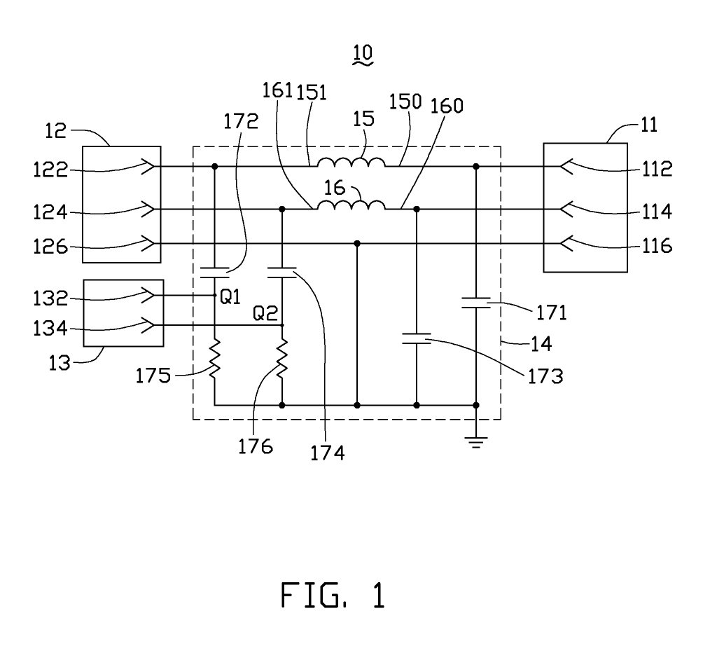

FIG. 1 is a line impedance stabilization network (LISN) 10 of the embodiment.

The LISN 10 includes a power port 11, an EUT connection port 12, an EMI output port 13, and a main circuit 14 connected between the power port 11, the EUT connection port 12, and the EMI output port 13. The power port 11 is configured to connect to an external power supply (such as a normal power source with 220 volt). The EUT connection port 12 is configured to connect to a EUT. The EMI output port 13 is configured to connect to EMI test equipment, such that the EMI test equipment can measure the EMI data of the EUT via the LISN 10.

The power port 11 includes a first terminal 112 for connecting a zero line of the power supply, a second terminal 114 for connecting a voltage line of the power supply, and a grounded terminal 116 for connecting a grounded line of the power supply. The EUT connection port 12 includes a first terminal 133 for connecting a zero terminal of the EUT, a second terminal 124 for connecting a voltage terminal of the EUT, and a grounded terminal 126 for connecting a grounded terminal of the EUT. The EMI output port 13 includes a first output terminal 132 and a second output terminal 134.

The main circuit 14 includes a first inductor 15, a second inductor 16, a first capacitor 171, a second capacitor 172, a third capacitor 173, a fourth capacitor 175, a first grounded resistor 175, and a second grounded resistor 176. The first inductor 15 is connected between the first terminal 112 of the power port 11 and the first terminal 122 of the EUT connection port 12. The second inductor 16 is connected between the second terminal 114 of the power port 11 and the second terminal 124 of the EUT connection port 12.

The first inductor 15 includes a first end 150 connected the first terminal 112 of the power port 11 and an opposite second end 151 connected the first terminal 122 of the EUT connection port 12. The second inductor 16 includes a first end 160 connected the second terminal 114 of the power port 11 and an opposite second end 161 connected the second terminal 124 of the EUT connection port 12. The first capacitor 171 is connected between the first end 150 of the first inductor 15 and the ground. An end of the second capacitor 172 is connected the second end 151 of the first inductor 15, and the other end of the second capacitor 172 is grounded via the first grounded resistor 175. The third capacitor 173 is connected between the first end 160 of the second inductor 16 and the ground. An end of the fourth capacitor 174 is connected the second end 161 of the second inductor 16, and the other end of the fourth capacitor 174 is grounded via the second grounded resistor 176.

The EMI output port 13 includes a first output terminal 132 and a second output terminal 134. The first output terminal 132 is connected a node Q1 between the second capacitor 172 and the first grounded resistor 175, and the second output terminal 134 is connected a node Q2 between the fourth capacitor 174 and the second grounded resistor 176.

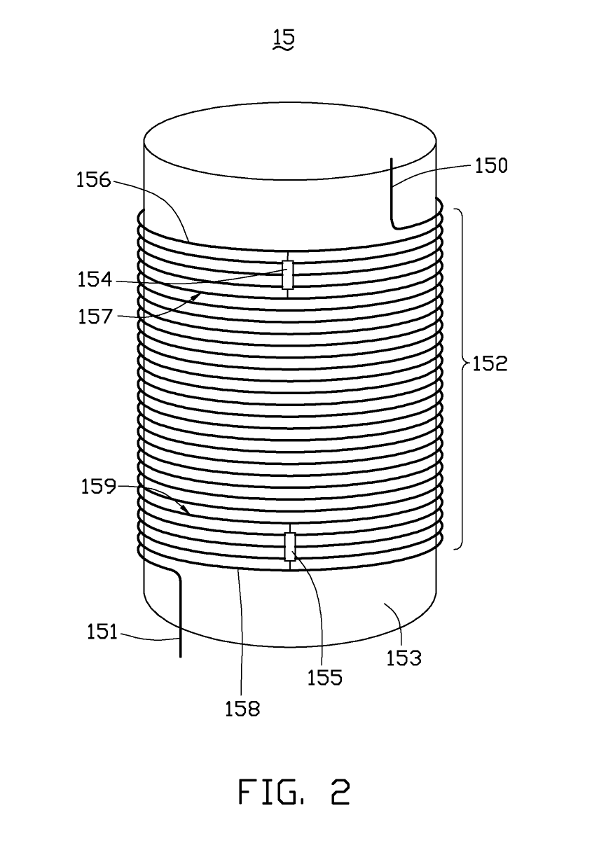

FIG. 2 shows that the first inductor 15 further includes a coil holder 153, a wire 152 connected between the first end 150 and second end 151, a first resistor 154, and a second resistor 155. The second inductor 16 may have the same structure with the first inductor 15. The wire 152 wraps around the coil holder 153 to form a plurality of coils. Each of the first resistor 154 and the second resistor 155 is connected between two different coils of the wire 152. In one embodiment, the plurality of coils includes a first coil 156 connected the first end 150 and a last coil 158 connected the second end 151. The first resistor 154 is connected between the first coil 156 and a number i coil 157 from the first end 150, and the second resistor 155 is connected between the last coil 158 and a number i coil 159 from the second end 151, where i≧2. In addition, a resistance of each of the first resistor 154 and the second resistor 155 ranges from 100 ohms to 1000 ohms In the embodiment, the number i=5, and a resistance of each of the first resistor and the second resistor is 430 ohms.

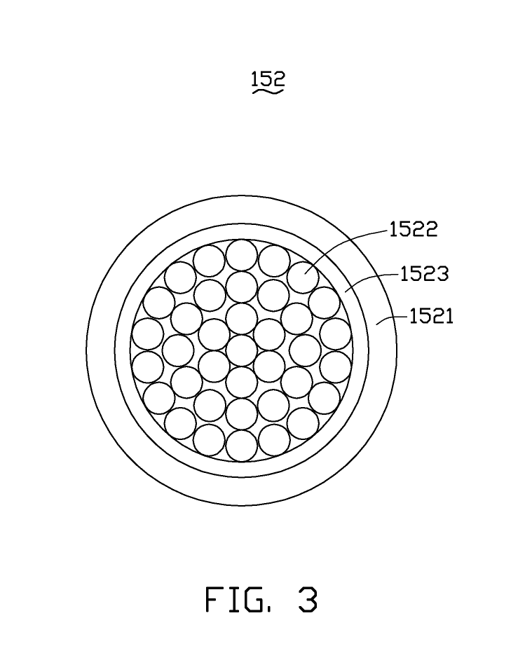

FIG. 3 shows a cross-sectional view of the wire 152 of the first inductor 15 of FIG. 2. The wire 152 comprises a plurality of metal leads 1522, a plastic cover 1521 surrounding the plurality of metal leads 1522 and a shielding layer 1523 located between the plastic cover 1521 and the metal leads 1523. The plurality of metal leads 1522 are copper leads and electrically contact each other.

Because of the first and the second resistors 154 and 155 two coils of the wire 152, the first inductor 15 can a receive a large current, accordingly, the reliability of the LISN 10 is improved.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in matters of shape, size and arrangement of parts within the principles of the present disclosure to the full extent indicated by the broad general meaning of the terms in which the appended claims are expressed.

What is claimed is:

1. A line impedance stabilization network (LISN), comprising:
a power port for connecting to a power supply;
an equipment under test (EUT) connection port for connecting to an EUT; and
a first inductor connected between the power port and the EUT connection port, the inductor comprising a first end, an opposite second end, a wire connected between the first end and the second end, and a first resistor, the wire comprising a plurality of coils, and the first resistor connected between two different coils of the wire.

2. The LISN of claim 1, wherein the plurality of coils define a first coil connected the first end and a last coil connected the second end, the first resistor is connected between the first coil and a number i coil from the first end, and i≧2.

3. The LISN of claim 2, wherein the first inductor further comprises a second resistor, and the second resistor is connected between the last coil and the number i coil from the last end.

4. The LISN of claim 3, wherein i is 5.

5. The LISN of claim 3, wherein a resistance of each of the first resistor and the second resistor ranges from 100 ohms to 1000 ohms.

6. The LISN of claim 3, wherein a resistance of each of the first resistor and the second resistor is 430 ohms.

7. The LISN of claim 1, wherein the first inductor further comprises a coil holder, the wire wraps around the coil holder to form the plurality of coils.

8. The LISN of claim 1, further comprising a first capacitor, a second capacitor, a grounded resistor, and an electromagnetic interference (EMI) output port for connecting an EMI test equipment, the first end is connected the power port, the second end is connected the EUT connection port, the first capacitor is connected between the first end and the ground, an end of the second capacitor is connected the second end, the other end of the second capacitor is grounded via the grounded resistor, and the EMI output port is connected a node between the second capacitor and the grounded resistor.

9. The LISN of claim 1, further comprising a second inductor, wherein the power port comprises a first terminal for connecting a zero line of the power supply, a second terminal for connecting a voltage line of the power supply, and a grounded terminal for connecting a grounded line of the power supply, the EUT connection port comprises a first terminal for connecting a zero terminal of the EUT, a second terminal for connecting a voltage terminal of the EUT, and a grounded terminal for connecting a grounded terminal of the EUT, the first inductor is connected between the first terminal of the power port and the first terminal of the EUT connection port, the second inductor is connected between the second terminal of the power port and the second terminal of the EUT connection port, and the grounded terminal of the power port is connected the grounded terminal of the EUT connection port.

10. The LISN of claim 9, further comprising a first capacitor, a second capacitor, a third capacitor, a fourth capacitor, a first grounded resistor, and a second grounded resistor, wherein the second inductor comprises a first end connected the second terminal of the power port and a second end connected the second terminal of the EUT connection port, the first end of the first inductor is connected the first terminal of the power port, the second end of the first inductor is connected the first terminal of the EUT connection port, the first capacitor is connected between the first end of the first inductor and the ground, an end of the second capacitor is connected the second end of the first inductor, the other end of the second capacitor is grounded via the first grounded resistor, the third capacitor is connected between the first end of the second inductor and the ground, an end of the fourth capacitor is connected the second end of the second inductor, the other end of the fourth capacitor is grounded via the second grounded resistor.

11. The LISN of claim 10, further comprising an EMI output port for connecting an EMI test equipment, wherein the EMI output port comprises a first output terminal and a second output terminal, the first output terminal is connected a node between the second capacitor and the first grounded resistor, and the second output terminal is connected a node between the fourth capacitor and the second grounded resistor.

12. The LISN of claim 1, wherein the wire comprises a plurality of metal leads and a plastic cover surrounding the plurality of metal leads.

13. The LISN of claim 12, wherein the plurality of metal leads electrically contact each other.

14. The LISN of claim 12, wherein the plurality of metal leads are copper leads.

15. The LISN of claim 12, wherein the wire further comprises a shielding layer located between the plastic cover and the metal leads.
